(19) United States
(12) Patent Application Publication
(10) Pub. No.: US 2021/0397505 A1
(43) Pub. Date: Dec. 23, 2021

(54) Stressed Epwr To Reduce Product Level DPPM/UBER

(71) Applicant: Western Digital Technologies, Inc., San Jose, CA (US)

(72) Inventors: Piyush DHOTRE, San Jose, CA (US); Sahil SHARMA, San Jose, CA (US); Mrinal KOCHAR, San Jose, CA (US); Shantanu GUPTA, Fremont, CA (US)

(21) Appl. No.: 16/905,783

(22) Filed: Jun. 18, 2020

(51) Int. Cl. G06F 11/07

(52) U.S. Cl. CPC G06F 11/0751; G06F 11/0793; G06F 11/0727

(57) ABSTRACT

The present disclosure generally relates to identifying read failures that enhanced post write/read (EPWR) would normally miss. After the last logical word line has been written, additional stress is added to each word line. More specifically, the gate bias channel pass read voltage for all unselected word lines is increased, the gate bias on dummy and selected gate word lines is increased, the gate bias on the selected word line is increased, and a pulse read occurs. The increasing and reading occurs for each word line. Thereafter, EPWR occurs. Due to the increasing and reading for every word line, additional read failures are discovered than would otherwise be discovered with EPWR alone.

### BACKGROUND

### Field

Embodiments of the present disclosure generally relate to identifying read failures.

### Description of the Related Art

Memory devices, such as 3D NAND memory devices, typically have three failure modes: program fails (PF), erase fails (EF), and read/uncorrectable error correction code (UECC) fails. Systems are generally better equipped to handle PF and EF issues such that the systems do not typically incur product level defective parts per million (DPPM)/uncorrectable bit error rate (UBER) issues. However, read/silent fails do result in DPPM/UBER issues.

Silent fails are mainly handled by an existing system algorithm called enhanced post write/read (EPWR). In EPWR, once the data is written in a TLC/QLC block, the system reads each word line to ensure that there are no silent fails. EPWR is expected to catch a portion of the silent fails that pop on the very first read. However, there are some fails that are not caught by EPWR, even after multiple reads.

Therefore, there is a need in the art for an improved EPWR to detect silent fails that would not normally be caught.

### SUMMARY

The present disclosure is generally related to identifying read failures that enhanced post write/read (EPWR) would normally miss. After the last logical word line has been written, additional stress is added to each word line. More specifically, the gate bias channel pass read voltage for all unselected word lines is increased, the gate bias on dummy and selected gate word lines is increased, the gate bias on the selected word line is increased, and a pulse read occurs. The increasing and reading occurs for each word line. Thereafter, EPWR occurs. Due to the increasing and reading for every word line, additional read failures are discovered than would otherwise be discovered with EPWR alone.

In one embodiment, a storage device comprises: a memory device; and a controller, wherein the controller is configured to: determine whether any erase failures (EFs) have occurred; program at least one logical word line; determine whether any program failures (PFs) have occurred; add additional stress to each logical word line; and determine whether any enhanced post write/read (EPWR) failures have occurred.

In another embodiment, a storage device comprises: a memory device; and a controller, wherein the controller is configured to: increase an unselected word line gate bias-channel pass read voltage for all unselected word lines; increase gate bias voltage on dummy and selected gate word lines; increase gate bias voltage on a selected word line; perform a pulse read; and determine whether any enhanced post write/read (EPWR) failures have occurred.

In another embodiment, a storage device comprises: a memory device; means to add additional stress to each logical word line of the memory device; means to determine whether any enhanced post write/read (EPWR) failures have occurred; and means to ensure that adding additional stress to each logical word line of the memory device occurs prior to determining whether any EPWR failures have occurred.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic block diagram illustrating a storage system having a storage device that may function as a storage device for a host device, in accordance with one or more techniques of this disclosure.

FIG. 2 is a flowchart of a prior art erase failure (EF), program failure (PF), and enhanced post write/read (EPWR) process according to the prior art.

FIGS. 3A and 3B are flowcharts of an erase failure (EF), program failure (PF), and enhanced post write/read (EPWR) process according to one embodiment of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to identifying read failures that enhanced post write/read (EPWR) would normally miss. After the last logical word line has been written, additional stress is added to each word line. More specifically, the gate bias channel pass read voltage for all unselected word lines is increased, the gate bias on dummy and selected gate word lines is increased, the gate bias on the selected word line is increased, and a pulse read occurs. The increasing and reading occurs for each word line. Thereafter, EPWR occurs. Due to the increasing and reading for every word line, additional read failures are discovered than would otherwise be discovered with EPWR alone.

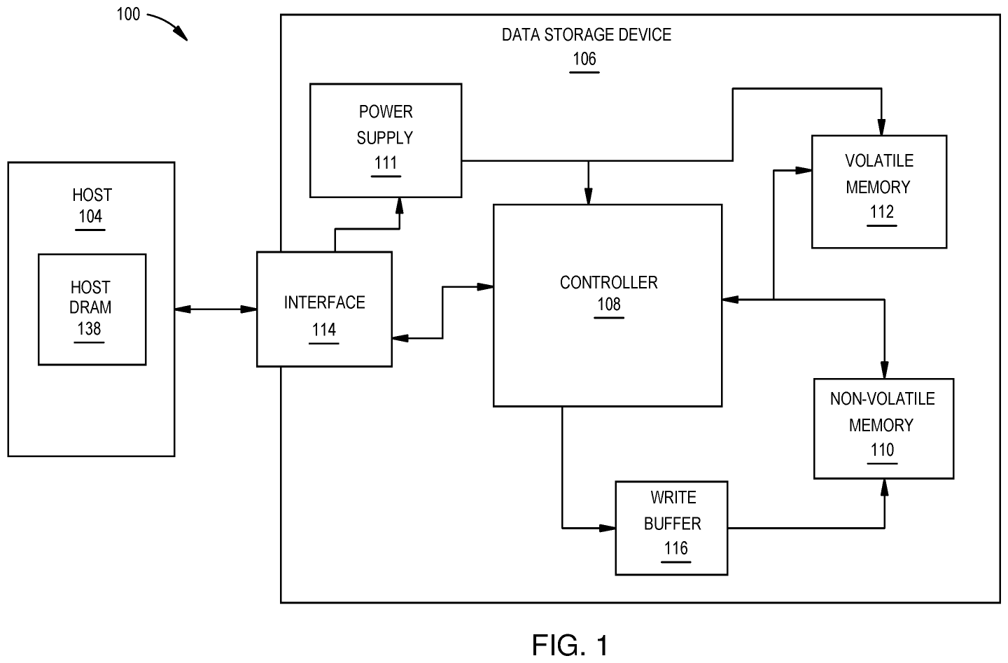

FIG. 1 is a schematic block diagram illustrating a storage system 100 in which data storage device 106 may function as a storage device for a host device 104, in accordance with one or more techniques of this disclosure. For instance, the host device 104 may utilize non-volatile memory (NVM) 110 included in data storage device 106 to store and retrieve data. The host device 104 comprises a host DRAM 138. In some examples, the storage system 100 may include a plurality of storage devices, such as the data storage device 106, which may operate as a storage array. For instance, the storage system 100 may include a plurality of data storage devices 106 configured as a redundant array of inexpensive/independent disks (RAID) that collectively function as a mass storage device for the host device 104.

The storage system 100 includes a host device 104 which may store and/or retrieve data to and/or from one or more storage devices, such as the data storage device 106. As illustrated in FIG. 1, the host device 104 may communicate with the data storage device 106 via an interface 114. The host device 104 may comprise any of a wide range of devices, including computer servers, network attached storage (NAS) units, desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, and the like.

The data storage device 106 includes a controller 108, NVM 110, a power supply 111, volatile memory 112, an interface 114, and a write buffer 116. In some examples, the data storage device 106 may include additional components not shown in FIG. 1 for sake of clarity. For example, the data storage device 106 may include a printed circuit board (PCB) to which components of the data storage device 106 are mechanically attached and which includes electrically conductive traces that electrically interconnect components of the data storage device 106, or the like. In some examples, the physical dimensions and connector configurations of the data storage device 106 may conform to one or more standard form factors. Some example standard form factors include, but are not limited to, 3.5″ data storage device (e.g., an HDD or SSD), 2.5″ data storage device, 1.8″ data storage device, peripheral component interconnect (PCI), PCI-extended (PCI-X), PCI Express (PCIe) (e.g., PCIe x1, x4, x8, x16, PCIe Mini Card, MiniPCI, etc.). In some examples, the data storage device 106 may be directly coupled (e.g., directly soldered) to a motherboard of the host device 104.

The interface 114 of the data storage device 106 may include one or both of a data bus for exchanging data with the host device 104 and a control bus for exchanging commands with the host device 104. The interface 114 may operate in accordance with any suitable protocol. For example, the interface 114 may operate in accordance with one or more of the following protocols: advanced technology attachment (ATA) (e.g., serial-ATA (SATA) and parallel-ATA (PATA)), Fibre Channel Protocol (FCP), small computer system interface (SCSI), serially attached SCSI (SAS), PCI, and PCIe, non-volatile memory express (NVMe), OpenCAPI, GenZ, Cache Coherent Interface Accelerator (CCIX), Open Channel SSD (OCSSD), or the like. The electrical connection of the interface 114 (e.g., the data bus, the control bus, or both) is electrically connected to the controller 108, providing electrical connection between the host device 104 and the controller 108, allowing data to be exchanged between the host device 104 and the controller 108. In some examples, the electrical connection of the interface 114 may also permit the data storage device 106 to receive power from the host device 104. For example, as illustrated in FIG. 1, the power supply 111 may receive power from the host device 104 via the interface 114.

The data storage device 106 includes NVM 110, which may include a plurality of memory devices or memory units. NVM 110 may be configured to store and/or retrieve data. For instance, a memory unit of NVM 110 may receive data and a message from the controller 108 that instructs the memory unit to store the data. Similarly, the memory unit of NVM 110 may receive a message from the controller 108 that instructs the memory unit to retrieve data. In some examples, each of the memory units may be referred to as a die. In some examples, a single physical chip may include a plurality of dies (i.e., a plurality of memory units). In some examples, each memory unit may be configured to store relatively large amounts of data (e.g., 128 MB, 256 MB, 512 MB, 1 GB, 2 GB, 4 GB, 8 GB, 16 GB, 32 GB, 64 GB, 128 GB, 256 GB, 512 GB, 1 TB, etc.).

In some examples, each memory unit of NVM 110 may include any type of non-volatile memory devices, such as flash memory devices, phase-change memory (PCM) devices, resistive random-access memory (ReRAM) devices, magnetoresistive random-access memory (MRAM) devices, ferroelectric random-access memory (F-RAM), holographic memory devices, and any other type of non-volatile memory devices.

The NVM 110 may comprise a plurality of flash memory devices or memory units. Flash memory devices may include NAND or NOR based flash memory devices, and may store data based on a charge contained in a floating gate of a transistor for each flash memory cell. In NAND flash memory devices, the flash memory device may be divided into a plurality of blocks which may be divided into a plurality of pages. Each block of the plurality of blocks within a particular memory device may include a plurality of NAND cells. Rows of NAND cells may be electrically connected using a word line to define a page of a plurality of pages. Respective cells in each of the plurality of pages may be electrically connected to respective bit lines. Furthermore, NAND flash memory devices may be 2D or 3D devices, and may be single level cell (SLC), multi-level cell (MLC), triple level cell (TLC), or quad level cell (QLC). The controller 108 may write data to and read data from NAND flash memory devices at the page level and erase data from NAND flash memory devices at the block level.

The data storage device 106 includes a power supply 111, which may provide power to one or more components of the data storage device 106. When operating in a standard mode, the power supply 111 may provide power to the one or more components using power provided by an external device, such as the host device 104. For instance, the power supply 111 may provide power to the one or more components using power received from the host device 104 via the interface 114. In some examples, the power supply 111 may include one or more power storage components configured to provide power to the one or more components when operating in a shutdown mode, such as where power ceases to be received from the external device. In this way, the power supply 111 may function as an onboard backup power source. Some examples of the one or more power storage components include, but are not limited to, capacitors, super capacitors, batteries, and the like. In some examples, the amount of power that may be stored by the one or more power storage components may be a function of the cost and/or the size (e.g., area/volume) of the one or more power storage components. In other words, as the amount of power stored by the one or more power storage components increases, the cost and/or the size of the one or more power storage components also increases.

The data storage device 106 also includes volatile memory 112, which may be used by controller 108 to store information. Volatile memory 112 may be comprised of one or more volatile memory devices. In some examples, the controller 108 may use volatile memory 112 as a cache. For instance, the controller 108 may store cached information in volatile memory 112 until cached information is written to non-volatile memory 110. As illustrated in FIG. 1, volatile memory 112 may consume power received from the power supply 111. Examples of volatile memory 112 include, but are not limited to, random-access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)).

The data storage device 106 includes a controller 108, which may manage one or more operations of the data storage device 106. For instance, the controller 108 may manage the reading of data from and/or the writing of data to the NVM 110. In some embodiments, when the data storage device 106 receives a write command from the host device 104, the controller 108 may initiate a data storage command to store data to the NVM 110 and monitor the progress of the data storage command. The controller 108 may determine at least one operational characteristic of the storage system 100 and store the at least one operational characteristic to the NVM 110. In some embodiments, when the data storage device 106 receives a write command from the host device 104, the controller 108 temporarily stores the data associated with the write command in the internal memory or write buffer 116 before sending the data to the NVM 110.

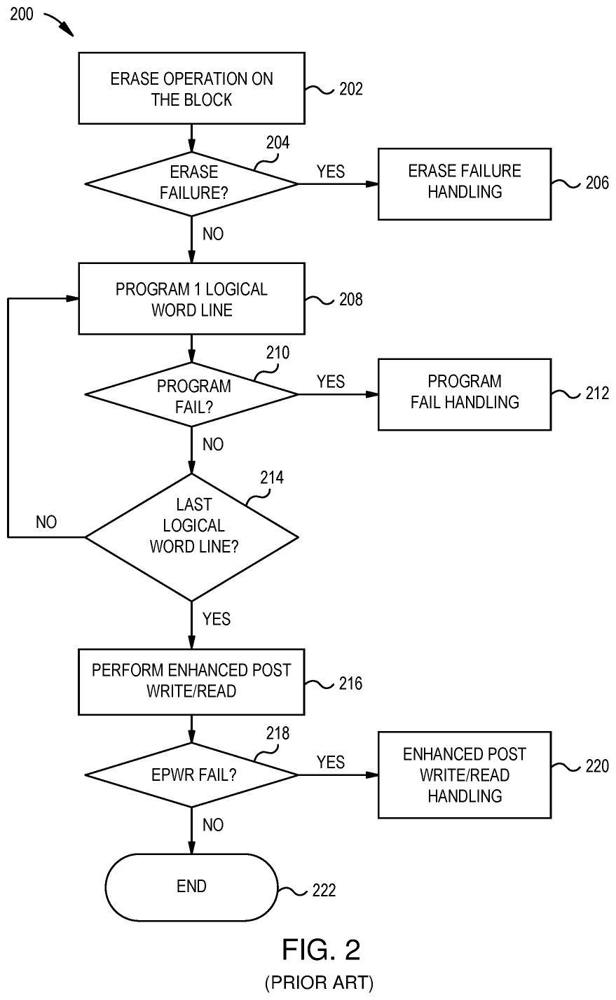

FIG. 2 is a flowchart of a prior art erase failure (EF), program failure (PF), and enhanced post write/read (EPWR) process according to the prior art. At 202, there is an erase operation on the block. The erase operation is done in one of two possibilities. In one example, in some flash memories, the entire chip is erased at one time. In another example, if less than all of the information stored on the chip is to be erased, the information must first be temporarily saved, and is usually written into another memory (typically a RAM). The information is then restored into nonvolatile flash memory by programming back into the chip.

At block 204, a determination is made regarding whether there has been an EF. If there has been an EF, then normal EF handling occurs at block 206. If there has been no EF at block 204, then the method proceeds to block 208. At block 208, a single logical word line is programmed. After block 208, a determination is made regarding whether there has been a PF at block 210. If a PF has occurred at block 210, then PF handling occurs at block 212. If no PF has occurred at block 210, then a determination is made regarding whether the just programmed single logical word line from block 208 is the last logical word line in block 214. If the just programmed single logical word line is not the last logical word line, then programming continues at block 208. If, however, the just programmed single logical word line is in fact the last logical word line in block 214, then an EPWR process is performed at block 216. At block 218, a determination is made regarding whether there has been an EPWR failure. If an EPWR failure has occurred at block 218, then EPWR handling occurs at block 220. If, however, an EPWR failure has not occurred at block 218, then the process completes at block 222.

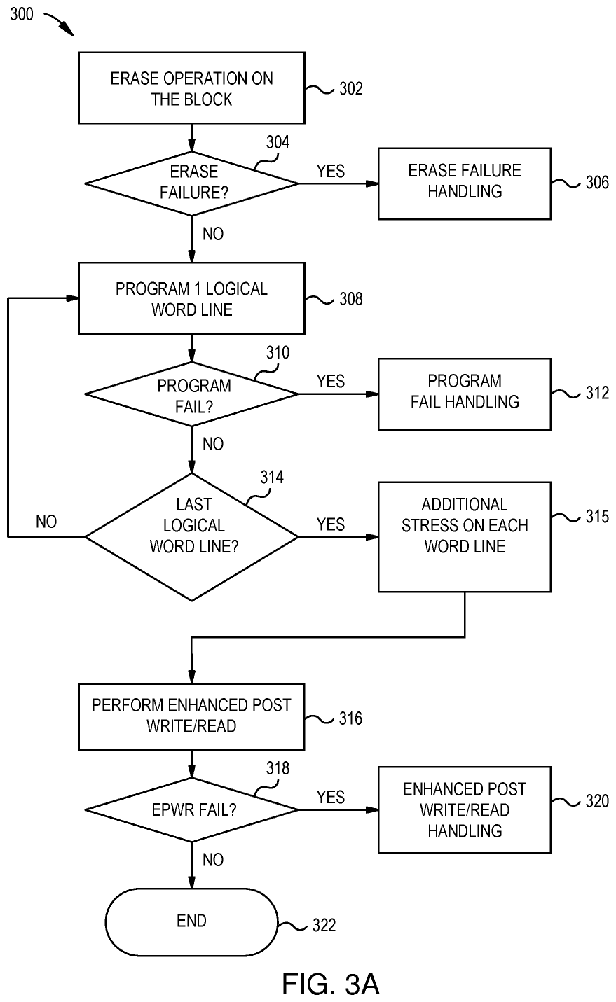

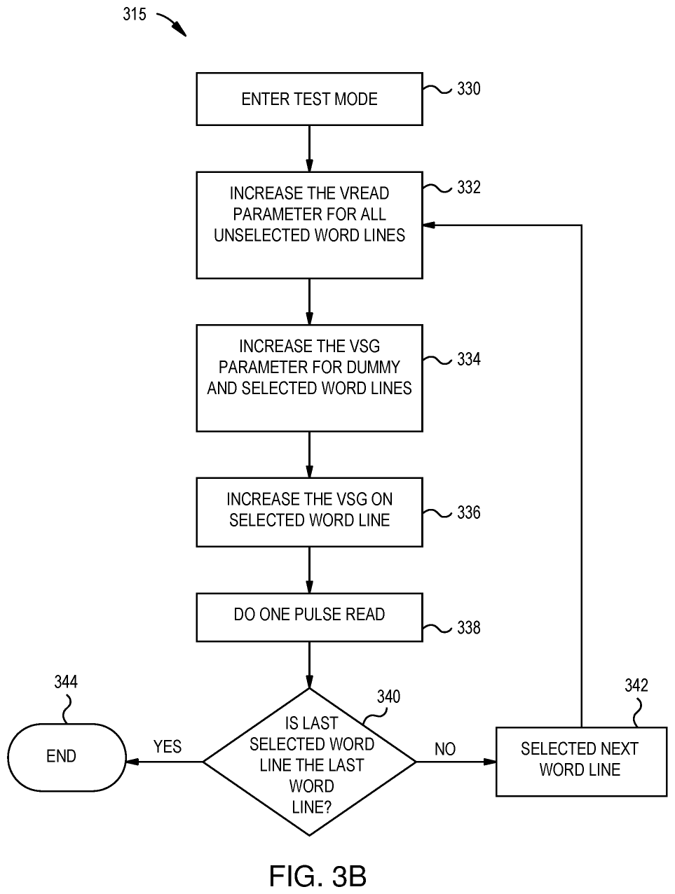

FIGS. 3A and 3B are flowcharts of an erase failure (EF), program failure (PF), and enhanced post write/read (EPWR) process according to one embodiment of the disclosure. At 302, there is an erase operation on the block. The erase operation is done in one of two possibilities. In one example, in some flash memories, the entire chip is erased at one time. In another example, if less than all of the information stored on the chip is to be erased, the information must first be temporarily saved, and is usually written into another memory (typically a RAM). The information is then restored into nonvolatile flash memory by programming back into the chip.

At block 304, a determination is made regarding whether there has been an EF. If there has been an EF, then normal EF handling occurs at block 306. If there has been no EF at block 304, then the method proceeds to block 308. At block 308, a single logical word line is programmed. After block 308, a determination is made regarding whether there has been a PF at block 310. If a PF has occurred at block 310, then PF handling occurs at block 312. If no PF has occurred at block 310, then a determination is made regarding whether the just programmed single logical word line from block 308 is the last logical word line in block 314. If the just programmed single logical word line is not the last logical word line, then programming continues at block 308. If, however, the just programmed single logical word line is in fact the last logical word line in block 314, then the process proceeds to block 315 where additional stress is added to each logical word line. Thereafter, an EPWR process is performed at block 316. At block 318, a determination is made regarding whether there has been an EPWR failure. If an EPWR failure has occurred at block 318, then EPWR handling occurs at block 320. If, however, an EPWR failure has not occurred at block 318, then the process completes at block 322.

At block 315, additional stress is added to each logical word line. The additional stress, in essence, mimics what is known as read disturb. FIG. 3B illustrates the method of applying the additional stress to each logical word line. At block 330, test mode is entered. All logical word lines have a gate bias-channel pass read voltage, oftentimes referred to as VREAD. VREAD is the voltage that need to be applied to a source electrode of a transistor coupled to a word line in order to read data. In test mode, initially, an individual logical word line is selected. At block 332, all of the unselected logical word lines have their VREAD parameter increased. In one embodiment, VREAD parameter is increased by about 2 volts. In other words, the voltage that must be applied in order to read data is increased by about 2 volts. Thus, a voltage applied to the source electrode that is less than VREAD will not result in a proper read and thus will not result in data being read. By increasing the VREAD parameter for the unselected word lines, when VREAD is applied to the selected word line, only the selected word line will be capable of being read because the selected word line will have a lower VREAD parameter than the unselected word lines.

Similarly, a gate bias, oftentimes referred to as VGATE of VSG, is the voltage that must be applied to a gate electrode of the transistor coupled to the respective word line in order to permit current to flow from a source electrode to a drain electrode of the transistor. At block 334, the VSG parameter is increased for all selected word line as well as a dummy word lines. In a given data block there are a certain number of data word lines where data will be programmed. There are additional word lines beyond the data word lines. The additional word lines are for selecting, deselecting, and isolating the data word lines. The additional word lines are referred to as dummy word lines. In one embodiment, the VSG is increased by about 1 volt. Hence, by increasing the VSG parameter, applying a voltage to the gate electrode that is below VSG will not result in a proper read and thus will not result in data being read.

At block 336, the VSG for the selected gate electrode of the selected word line. A pulse read occurs in block 338 by applying VREAD to the source electrode. The pulse read will determine whether the pulse width of the selected word line falls within the threshold of the higher increase time and lower increase time which is predetermined. This will determine if the word line passes or fails. A pass will result from a word line pulse width being within that predetermined threshold. A failure will result from a word line pulse width being outside of that predetermined threshold.

Thereafter, a determination is made at block 340 regarding whether the selected word line is the last word line. If the selected word line is not the las word line at block 340, then the next word line is selected at block 342 and the process repeats at block 332. If, however, the selected word line is the last word line, then the additional stress process ends at block 344.

By increasing the voltage for all unselected word lines, increasing the gate bias on dummy and selected gate word lines, increasing the gate bias on the selected word line, performing a pulse read, and doing so for each word line, additional read failures are discovered than would otherwise be discovered with EPWR alone.

In one embodiment, a storage device comprises: a memory device; and a controller, wherein the controller is configured to: determine whether any erase failures (EFs) have occurred; program at least one logical word line; determine whether any program failures (PFs) have occurred; add additional stress to each logical word line; and determine whether any enhanced post write/read (EPWR) failures have occurred. The controller is configured to add additional stress to each logical word line after the last logical word line has been programmed. Adding additional stress to each logical word line comprises increasing VREAD for all unselected word lines. Adding additional stress to each logical word line comprises increasing VSG on dummy and selected gate word lines. Adding additional stress to each logical word line comprises increasing VSG on a selected word line. Adding additional stress to each logical word line comprises performing a pulse read. Determining whether any EPWR failures have occurred occurs after adding additional stress to each logical word line.

In another embodiment, a storage device comprises: a memory device; and a controller, wherein the controller is configured to: increase an VREAD for all unselected word lines; increase VSG on dummy and selected gate word lines; increase VSG on a selected word line; perform a pulse read; and determine whether any enhanced post write/read (EPWR) failures have occurred. The controller is configured to perform erase failure correction. The controller is configured to perform program failure correction. The controller is configured to perform EPWR failure correction. The increasing VREAD for all unselected word lines occurs after an entire block of the memory device has been closed. The increasing VREAD for all unselected word lines, the increasing VSG on dummy and selected gate word lines, the increasing VSG on a selected word line, and the performing a pulse read occurs on all logical word lines. The increasing VREAD for all unselected word lines, the increasing VSG on dummy and selected gate word lines, the increasing VSG on a selected word line, and the performing a pulse read occurs only one time per logical word line.

In another embodiment, a storage device comprises: a memory device; means to add additional stress to each logical word line of the memory device; means to determine whether any enhanced post write/read (EPWR) failures have occurred; and means to ensure that adding additional stress to each logical word line of the memory device occurs prior to determining whether any EPWR failures have occurred. The storage device further comprises: means to increase VREAD for all unselected word lines; means to increase VSG on dummy and selected gate word lines; means to increase VSG on a selected word line; means to perform a pulse read; and means to determine whether any enhanced post write/read (EPWR) failures have occurred. The storage device further comprises means to repeat increasing VREAD for all unselected word lines, increasing VSG on dummy and selected gate word lines, increasing VSG on a selected word line, and performing a pulse read for all logical word lines. The storage device further comprises means to determine if all logical word lines of a block of the memory device have been programmed. The storage device further comprises means to perform erase failure detection and correction. The storage device further comprises means to perform program failure detection and correction.

While the foregoing is directed to embodiments of the present disclosure, other and further embodiments of the disclosure may be devised without departing from the basic scope thereof, and the scope thereof is determined by the claims that follow.

1. A storage device, comprising:
a memory device; and
a controller, wherein the controller is configured to:
determine whether any erase failures (EFs) have occurred;
program at least one logical word line;
determine whether any program failures (PFs) have occurred;
add additional stress to each logical word line, wherein adding additional stress comprises:
increasing VREAD for each unselected wordline;
increasing VSG for each dummy wordline and each selected gate word lines; and
increasing VSG on a selected word line; and
determine whether any enhanced post write/read (EPWR) failures have occurred.

2. The storage device of claim 1, wherein the controller is configured to add additional stress to each logical word line after the last logical word line has been programmed.

3-5. (canceled)

6. The storage device of claim 1, wherein adding additional stress to each logical word line comprises performing a pulse read.

7. The storage device of claim 1, wherein determining whether any EPWR failures have occurred occurs after adding additional stress to each logical word line.

8. A storage device, comprising:
a memory device; and
a controller, wherein the controller is configured to:
increase VREAD for all unselected word lines;
increase VSG on dummy and selected gate word lines;
increase VSG on a selected word line;
perform a pulse read; and
determine whether any enhanced post write/read (EPWR) failures have occurred.

9. The storage device of claim 8, wherein the controller is configured to perform erase failure correction.

10. The storage device of claim 8, wherein the controller is configured to perform program failure correction.

11. The storage device of claim 8, wherein the controller is configured to perform EPWR failure correction.

12. The storage device of claim 8, wherein the increasing VREAD for all unselected word lines occurs after an entire block of the memory device has been closed.

13. The storage device of claim 8, wherein the increasing VREAD for all unselected word lines, the increasing VSG on dummy and selected gate word lines, the increasing VSG on a selected word line, and the performing a pulse read occurs on all logical word lines.

14. The storage device of claim 13, wherein increasing VREAD for all unselected word lines, the increasing VSG on dummy and selected gate word lines, the increasing VSG on a selected word line, and the performing a pulse read occurs only one time per logical word line.

15. A storage device, comprising:
a memory device;
means to add additional stress to each logical word line of the memory device;
means to increase VREAD for all unselected word lines;
means to increase VSG on dummy and selected gate word lines;
means to increase VSG on a selected word line;
means to determine whether any enhanced post write/read (EPWR) failures have occurred; and
means to ensure that adding additional stress to each logical word line of the memory device occurs prior to determining whether any EPWR failures have occurred.

16. The storage device of claim 15, further comprising:
means to perform a pulse read; and
means to determine whether any enhanced post write/read (EPWR) failures have occurred.

17. The storage device of claim 16, further comprising means to repeat increasing VREAD for all unselected word lines, increasing VSG on dummy and selected gate word lines, increasing VSG on a selected word line, and performing a pulse read for all logical word lines.

18. The storage device of claim 15, further comprising means to determine if all logical word lines of a block of the memory device have been programmed.

19. The storage device of claim 15, further comprising means to perform erase failure detection and correction.

20. The storage device of claim 15, further comprising means to perform program failure detection and correction.
